(19) United States
(12) Patent Application Publication
(10) Pub. No.: US 2026/0101689 A1
(43) Pub. Date: Apr. 9, 2026

(54) METHOD FOR PLASMA ETCHING VERTICAL FEATURES IN A SILICON-BASED SEMICONDUCTOR LAYER OF A SUBSTRATE

(71) Applicant: Tokyo Electron Limited, Tokyo (JP)

(72) Inventors: Du Zhang, Albany, NY (US); Yu-Hao Tsai, Albany, NY (US); Takeshi Oyama, Miyagi (JP); Toru Hisamatsu, Miyagi (JP); Tetsuya Nishizuka, Miyagi (JP)

(21) Appl. No.: 18/909,694

(22) Filed: Oct. 8, 2024

(51) Int. Cl. H01L 21/3065; H01J 37/32; H01L 21/308

(52) U.S. Cl. CPC H10P 50/242; H01J 37/32449; H10P 50/691; H01J 2237/334

(57) ABSTRACT

A method for plasma etching in a plasma processing chamber, where the method includes providing a substrate having a silicon-based semiconductor layer disposed over an etch stop layer and a patterned masking layer disposed over the silicon-based semiconductor layer, the patterned masking layer exposing a surface of the silicon-based semiconductor layer; using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process including generating a first plasma; and vertically etching in situ the pattern of lines using a second plasma etch process, the second plasma etch process including generating a second plasma from a first gas including chlorine and a second gas including a compound of hydrogen with Si, Br, I, P, or S, the second plasma being different from the first plasma, and exposing the pattern of lines to the second plasma to remove the foot from the pattern of lines.

### TECHNICAL FIELD

The present invention relates generally to a method for plasma etching, and, in particular embodiments, to a method for plasma etching vertical features in a silicon-based semiconductor layer of a substrate.

### BACKGROUND

An integrated circuit (IC) is a network of electronic components and multi-level wiring forming a monolithic structure. An array of IC units is fabricated in a substrate by sequentially building a stack of layers starting from a semiconductor substrate and processing the substrate through a sequence patterning levels. At each patterning level, a patterned layer is formed using deposition, lithography, and etch techniques, many of which are plasma processes. Almost every two years, a new IC design node is offered with a component density doubled using advances in patterning technology. The density doubling is achieved with three dimensional (3D) devices and shrinking lateral dimensions, a combination that leads to etching high aspect ratio features with nanometer-scale lateral dimensions. Electrical performance and variability of electronic devices are often sensitive to the etch profile (e.g., sidewall slope, footing, and bowing) and size of etched features critical to the final device structure. For example, transistor drive and leakage currents of nanosheet field effect transistors (FETs) and FinFETs are sensitive to the etch profile, linewidth, and line width roughness (LWR) of silicon lines that define their gate lengths. Thus, plasma technology is challenged to provide etch processes with almost atomic level control of linewidth, LWR, and etch profile to achieve high yield. With scaling continuing toward sub-5 nm nodes, further innovation in plasma etch processes would be beneficial for advanced IC manufacturing.

### SUMMARY

A method for plasma etching in a plasma processing chamber, where the method includes providing a substrate having a silicon-based semiconductor layer disposed over an etch stop layer and a patterned masking layer disposed over the silicon-based semiconductor layer, the patterned masking layer exposing a surface of the silicon-based semiconductor layer; using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process including generating a first plasma; and vertically etching in situ the pattern of lines using a second plasma etch process, the second plasma etch process including generating a second plasma from a first gas including chlorine and a second gas including a compound of hydrogen with Si, Br, I, P, or S, the second plasma being different from the first plasma, and exposing the pattern of lines to the second plasma to remove the foot from the pattern of lines.

A method for plasma etching, where the method includes flowing a gas over a substrate in a plasma processing chamber, the substrate including: an etch stop layer; a patterned silicon-based semiconductor layer disposed over the etch stop layer, the pattern including lines and openings between the lines, each of the lines having a foot along its base and each of the openings exposing a surface of an etch stop layer, and a patterned masking layer disposed over the patterned silicon-based semiconductor layer, the patterned masking layer being a topmost layer of the substrate; generating a plasma by ionizing the gas in the plasma processing chamber, the gas including: a first gas including an etchant; and a second gas including a scavenging and deposition agent; and exposing the substrate to the plasma to remove the foot, the exposing including scavenging the etchant while depositing a protective layer over the patterned masking layer.

A method for plasma etching in a plasma processing chamber, where the method includes providing a substrate having a silicon-based semiconductor layer disposed over an etch stop layer and a patterned masking layer disposed over the silicon-based semiconductor layer, the patterned masking layer exposing a surface of the silicon-based semiconductor layer; using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process including generating a first plasma from a first gas including chlorine, and exposing the substrate to the first plasma; and vertically etching in situ the pattern of lines using a second plasma etch process, the second plasma etch process including generating a second plasma from the first gas and a second gas including a compound of hydrogen with Si, Br, I, P, or S, and exposing the pattern of lines to the second plasma to remove the foot from the pattern of lines.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of a substrate comprising IC devices prior to plasma etching a silicon-based semiconductor layer, in accordance with an embodiment of the invention;

FIG. 2 illustrates a cross-sectional view of the substrate in FIG. 1 at the end of a main etch step, in accordance with an embodiment of the invention;

FIG. 3 illustrates the cross-sectional view of the substrate in FIG. 2 after completing an overetch step, in accordance with an embodiment of the invention; and

FIG. 4 illustrates a flow chart of a method for plasma etching vertical features in a silicon-based semiconductor layer of a substrate, in accordance with an embodiment of the invention.

### DETAILED DESCRIPTION OF ILLUSTRATIVE EMBODIMENTS

Fabrication flows of electronic devices frequently have silicon-based semiconductor lines defining critical dimensions (CDs) of the electronic devices, which affect their electrical characteristics. Examples include fabrication of field-effect transistors (FETs), where some of the critical device dimensions that affect transistor currents, viz., gate length (L_{g}) and fin width (W_{FIN}), are defined by respective patterns of silicon-based semiconductor lines. In such applications, it is desirable that a plasma etch process for etching a silicon-based semiconductor layer be used that is suitable for providing lines having a vertical sidewall for precise CD control and a smooth sidewall surface for low line width roughness (LWR) of the gates and high mobility of charge carriers transporting current along semiconductor fins of a FinFET. This disclosure describes embodiments of a method that provides the advantages of plasma etching vertical features with smooth sides in a silicon-based semiconductor layer of a substrate. The plasma etch processes described herein include an overetch step, where an anisotropic reactive ion etching (aRIE) process is performed using plasma generated from a gas comprising an etchant and gaseous additives comprising chemical agents for scavenging the etchant and for depositing a passivating layer over surfaces to be protected from being etched by the etchant.

It is noted that the final CD, LWR, and surface roughness of features patterned in the silicon-based semiconductor layer depend not only on the method for etching the layer but also on methods related to forming a patterned masking layer over the silicon-based semiconductor layer for the etching. The patterned masking layer comprises a pattern of openings, where each of the openings exposes a portion of the silicon-based semiconductor layer to etchants during the plasma etch process used to etch the silicon-based semiconductor layer. The embodiments described in this disclosure pertain to etching the silicon-based semiconductor layer using the patterned masking layer.

Several important electrical metrics of the FET depend on L_{g} and hence on a gate etch process that defines L_{g}. For example, the total gate capacitance (C_{gate}) of the FET, which is a capacitance between a gate electrode and a transistor channel in the fin, is proportional to a gate area, hence C_{gate} is proportional to L_{g}. Other metrics of the FET that depend on L_{g} include its drive current (I_{ON}) and leakage current (I_{OFF}), as explained in detail further below. Note that the L_{g} that is relevant for the transistor metrics (e.g., C_{gate}, I_{ON}, and I_{OFF}) is the bottom CD of the silicon-based semiconductor line that defines the gate.

In addition to being used as the gate electrode of FETs, gates formed between fins may be used as signal lines that transport electrical signals. In this application, a low line resistance is desired for circuit speed, along with a low line-to-line capacitance to reduce crosstalk due to capacitive coupling between adjacent lines in a dense array of signal lines. Thus, control of CD as well as control of etch profile is important. A gate etch profile having footing increases the line-to-line capacitance by reducing a space between adjacent gates near a base of the gates. A profile with bowing and notching may increase the line resistance.

The I_{ON} and I_{OFF} show an explicit dependence on L_{g}, the dependence being I_{ON} and I_{OFF} are roughly proportional to 1/L_{g}. In addition, I_{ON} and I_{OFF} depend implicitly on L_{g} via the impact of L_{g} on a threshold voltage (V_{T}), where V_{T} is a parameter affecting both I_{ON} and I_{OFF}. The V_{T} depends on a set of physical characteristics of the FET that includes L_{g}. By definition, V_{T} is a gate voltage condition that marks a boundary between two operating regions: a high current “strong inversion” region and a low current “subthreshold” region. During operation, the gate voltage may be varied through V_{T} for the FET to make a transition between strong inversion and subthreshold. When biased in subthreshold, the transistor current changes exponentially with gate voltage. In contrast, in strong inversion, the transistor current has a weaker response to the gate voltage. At short gate lengths, |V_{T}|decreases with decreasing L_{g} because of a V_{T}-rolloff effect, which increases both I_{ON} and I_{OFF}. Thus, at longer L_{g}, where the V_{T} is roughly constant, I_{ON} and I_{OFF} has simply the 1/L_{g} dependence, mentioned above, but FETs having gate lengths close to the minimum allowed by the design rules, both I_{ON} and I_{OFF} are more sensitive to L_{g} because of the implicit dependence of transistor currents on L_{g}. Overall, this worsens variability of FET characteristics. Generally, V_{T}-rolloff has a more striking impact on I_{OFF} than on I_{ON} because of the exponential response of subthreshold current to gate voltage. For example, a 20 % increase in I_{ON} due to V_{T}-rolloff may be costing roughly a hundred times higher I_{OFF}. Clearly, CD control at the gate patterning level is necessary to control the performance and yield of FET devices.

Generally, CD of a feature (e.g., a line or an opening) refers to a local average of a width of the feature. The measure is called a “local average” because it is an average value that is assigned to the location of the measured feature. Typically, the measurement represents an average over a length greater than its width, or an average of a plurality of measurements obtained from an array of closely spaced identically designed features. Note that the local average linewidth “averages out” local random linewidth variations (i.e., linewidth variations over distances much shorter than the local average linewidth). However, systematic linewidth variations are retained. Examples of systematic variations include pattern density dependent linewidth variation and linewidth variations over long distances, for example, from a central region to an edge region of the substrate. The systematic linewidth variation is described by the CD variation, and the local random linewidth variation is described by the LWR, commonly defined as three times a standard deviation (3-sigma) of the local random linewidth variation.

As mentioned above, L_{g} variations include a contribution from linewidth variation in the patterned masking layer. The etch process superposes on that its own independent contribution to variation in L_{g}. In this disclosure, we focus on the etch process. A plasma process for etching the silicon-based semiconductor lines that define L_{g} may affect systematic variations as well as the LWR of L_{g}. For example, systematic variation in L_{g} may be caused by center-to-edge variation in plasma properties that affect etch selectivity and sidewall angle. (Here, sidewall angle is the angle between the sidewall and the vertical direction, i.e., the sidewall angle is zero degree for a vertical sidewall.) Contributions to the LWR of L_{g} may come from stochastic processes related to plasma etching. Examples of this may include fluctuations of an etch-related parameter (such as an ion flux or an ion energy) along the length of the feature.

As mentioned above, the gate dimension that is relevant for the transistor currents (as well as C_{gate}) is the bottom CD of the silicon-based semiconductor line that defines the gate. Since sensitivity of the bottom CD to sidewall angle diminishes as the angle approaches zero, a vertical sidewall profile advantageously reduces systematic variation in L_{g}. Since I_{ON} and I_{OFF} depend on L_{g}, reducing the systematic variation in L_{g} reduces systematic variations in I_{ON} and I_{OFF}.

The local random variation in L_{g}, or, the LWR, also affects I_{ON} and I_{OFF}. Consider two FETs having different gate LWR but are physically identical in all other respects (e.g., same doping profiles, gate dielectric thickness etc.). The random variations in L_{g} average out for the two FETs, resulting in both having equal local average L_{g}, irrespective of their difference in gate LWR. However, the transistor currents of the FETs, being nonlinear functions of L_{g}, do not average out to the same I_{ON} and I_{OFF}. The FET with the higher LWR would have a higher I_{ON} as well as a higher I_{OFF}. Furthermore, because I_{OFF} is more sensitive to L_{g} than I_{ON} (as described above), LWR undesirably reduces a ratio of I_{ON} to I_{OFF} (a common performance metric for FETs): Of the two FETs, the FET with the higher LWR would have the worse I_{ON}/I_{OFF} ratio. Similar to the effects of the systematic variation in L_{g} (discussed above), these effects of LWR become more prominent at short L_{g}, i.e., L_{g} approximately equal to the minimum allowed by the design rules.

Another example of etching a silicon-based semiconductor layer to define a critical dimension of an electronic device is etching a pattern of lines in a silicon layer or a stack of alternating silicon and silicon-germanium layers (called nanosheets) to define a fin width (W_{FIN}) of FETs such as FinFETs and nanosheet FETs. The etched stack of nanosheets is sometimes referred to as a pillar instead of as a fin. The fins of a FinFET structure are fin-shaped protrusions formed by a patterning process that includes etching a pattern of lines in a starting substrate, for example, a silicon-on-insulator (SOI) substrate. An anisotropic silicon etch process providing smooth vertical fins of the FinFET may reduce surface roughness scattering and hence, enhance mobility of charge carriers transporting current along the etched surfaces. In narrow fins, the mobility also depends on W_{FIN}. The dependence is due to a quantum size effect that pushes a centroid of the mobile charge away from the fin surfaces, thus enhancing mobility and the transistor's I_{ON} by reducing the impact of surface scattering. The quantum size effect also increases the FinFET's threshold voltage, V_{T}. As discussed above, V_{T} is a parameter affecting both I_{ON} and I_{OFF}. Thus, a dependence of V_{T} on W_{FIN} leads to an implicit dependence of I_{ON} and I_{OFF} on W_{FIN}, similar to the implicit dependence of I_{ON} and I_{OFF} on L_{g}. Since quantization effects get more conspicuous as the dimension in which particles are confined is shrunk, I_{ON} and I_{OFF} become increasingly sensitive to W_{FIN} as the W_{FIN} of FinFETs is reduced. With W_{FIN} scaled to below 10 nm, CD control at the fin patterning level is important for control of I_{ON} and I_{OFF}.

In general, electrical performance and variability of integrated circuit (IC) components, including transistors, become more sensitive to lateral dimensions and etch profiles of etched features as feature sizes are reduced at critical patterning levels leading to patterning features having high aspect ratios. As explained above, in many patterning applications, it is desirable to pattern features having sidewalls that are vertical and smooth. To that purpose, anisotropic plasma etch processes that provide an ideal etch profile that is perfectly vertical and free of bowing, footing, or notching is desired.

As mentioned above, aRIE processes are commonly used for etching vertical features in silicon-based semiconductor layers. Although an aRIE process is designed to etch vertically, the etch rate has both vertical and lateral components. As explained further below, in a high aspect ratio opening, the vertical etch rate drops proximate the sidewall, resulting in a foot near the base of the etched feature. This disclosure describes embodiments of plasma etch processes, where an etch chemistry of an overetch step is designed to remove the foot to form a vertical sidewall without creating a notch or a re-entrant edge. In various embodiments of the plasma etch processes described in this disclosure, the etching exposes a surface of an underlying layer formed below the silicon-based semiconductor layer, where the etch chemistry and the layer materials have been selected to use the underlying layer as an etch stop layer. The overetch step, which removes the foot, is performed after an etch depth of the etched feature has reached the underlying layer. The higher etch resistance of the underlying layer (relative to the silicon-based semiconductor layer above the underlying layer) enables the overetch process to remove the foot without significantly increasing the etch depth further.

For example, the gate etch process (the etch process that defines L_{g}) first etches a pattern of openings in the silicon-based semiconductor layer (e.g., a silicon layer) deposited over the underlying layer (e.g. a silicon oxide etch stop layer) till the silicon oxide etch stop layer is exposed. As the opening gets deeper during etching, the vertical etch rate reduces, with the reduction being more prominent nearer to the sidewall. This results in laterally nonuniform etching where, in any horizontal plane deep inside the opening, the vertical etch rate is increasing with increasing distance from the sidewall. Because of this lateral nonuniformity, the silicon oxide is exposed first in a central region of the openings between the adjacent lines and a large foot comprising silicon is formed along a lower portion of the lines. Accordingly, the bottom CD of the silicon line is large and a width of the exposed silicon oxide surface is small. The overetch step is then performed to remove the foot. By removing the foot, the overetch step expands the width of the exposed silicon oxide surface and shrinks the bottom CD to a desired value to form a vertical sidewall. The overetch step of the embodiments (described in further detail below) is an aRIE process where the etch chemistry includes chemical agents for the scavenging and passivating reactions mentioned above. During the foot removal, the higher etch resistance of the underlying layer stops the vertical depth of the opening from increasing further, while the lateral expansion of the width of the exposed silicon oxide surface continues by removing the silicon material from the foot.

Another example of an aRIE process for etching a silicon-based semiconductor layer is the fin etch that defines W_{FIN} for FinFETs on SOI. In a commonly used SOI starting substrate, there is a crystalline silicon layer on one side of the SOI substrate. This crystalline silicon layer is referred to here as an active silicon layer. The active silicon layer is separated from a thicker silicon layer on the opposite side of the SOI substrate by a relatively thin silicon oxide layer, referred to as a buried oxide layer, or, BOX. The thicker silicon layer is typically much thicker than either the BOX or the active silicon layer. In this example, the active silicon layer is the silicon-based semiconductor layer, and the underlying etch stop layer is the BOX. The active silicon layer is patterned to form fin-shaped silicon lines which may be part of FinFETs. The aRIE process described herein may be used for etching the active silicon layer to form the fins.

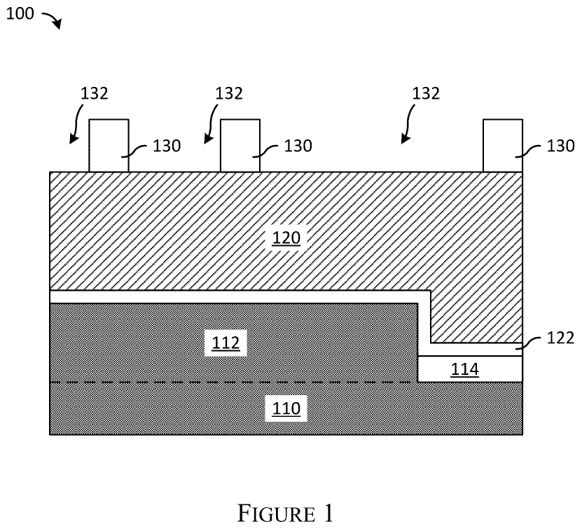

An example embodiment of the plasma etch method is now described with reference to FIGS. 1-3. For specificity, the example aRIE process for etching the silicon-based semiconductor layer is an embodiment, where the aRIE process is for etching a sacrificial silicon layer used in a replacement gate process flow for fabricating FinFETs on a bulk silicon substrate.

FIG. 1 illustrates a cross-sectional view of a substrate 100 comprising IC devices at an intermediate stage of fabrication starting from, for example, a bulk silicon substrate 110. The bulk silicon substrate 110 has been patterned to form a pattern of fins 112 protruding above the bulk silicon substrate 110, such as the fin 112 illustrated in FIG. 1. A double patterning technique, known as sidewall image transfer (SIT), commonly used for fin patterning, may be used here for patterning the bulk silicon substrate 110. In the SIT technique, an etch mask for the fin etch is a pattern of spacers formed initially along sidewalls of a pattern of sacrificial mandrels. The mandrels are removed selectively, leaving behind the pattern of spacers covering a portion of a surface of the bulk silicon substrate 110. The fin etch transfers the pattern of spacers to the bulk silicon substrate 110 by etching trenches of a desired depth using aRIE. Thus, there is a trench on opposite sides of each fin 112 in the pattern of fins 112. The fins 112 are part of electronic devices such as FinFETs, diodes, and gate capacitors, although some of the fins 112 may be dummy structures that enhance pattern uniformity.

Note that, in this example, the starting substrate is a bulk silicon substrate and not an SOI substrate. Accordingly, there is no BOX separating the fin 112 from the bulk silicon substrate 110. As illustrated in FIG. 1, the fins are etched in bulk silicon, where there is no underlying layer for the fin etch to stop on. Hence, as explained above, the foot removal technique used in the embodiments of the plasma etch processes described herein is not applicable to the aRIE process used to form the pattern of fins 112 in FIG. 1.

After fin patterning, the relatively deep trenches may be filled with an insulator (e.g., silicon oxide). In FIG. 1, the insulator has been etched back by a selective recess etch to expose an upper portion of the fin 112. A lower portion of the fin 112 is surrounded by the now recessed insulating layer, referred to as a shallow trench isolation (STI) layer 114. The STI layer 114 provides electrical insulation between adjacent fins 112, which helps in electrically isolating neighboring electronic devices such as FinFETs, which are built with fins 112. Note that forming the fins 112 divides the substrate 100 into two contiguous regions: an active region and an isolation region. In the cross-sectional view illustrated in FIG. 1, the active region is the area where the fin 112 is present, and the isolation region is the area containing the STI layer 114.

After completing the recess etch, the substrate 100 has been further processed to deposit an underlying layer 122 and a sacrificial gate layer 120 over the underlying layer 122. As mentioned above, the sacrificial gate layer 120 is the layer to be etched and the underlying layer 122 may be used as an etch stop layer. As also mentioned above, for specificity, the layer to be etched is a silicon layer, hence the example embodiment is an aRIE process for etching silicon. Accordingly, the sacrificial gate layer 120 in FIG. 1 may be comprising amorphous silicon or polycrystalline silicon and may be about 30 nm to about 100 nm thick. In various embodiments, a thickness of the silicon-based semiconductor layer (the layer to be etched) may be from about 30 nm to about 200 nm. Since the underlying layer 122 may also be an etch stop layer, in various embodiments, the underlying layer 122 may comprise silicon oxide, silicon oxynitride, or silicon nitride. A thickness of the underlying layer 122 may be from about 3 nm to about 40 nm.

As illustrated in FIG. 1, the thin underlying layer 122 and the sacrificial gate layer 120 have been formed conformally over the fins 112 and the STI layer 114 using a suitable technique, (e.g., chemical vapor deposition (CVD) and plasma enhanced CVD). In some embodiments, such as the example illustrated in FIG. 1, the surface of the sacrificial gate layer 120 may be planarized using, for example chemical-mechanical polishing (CMP).

In the example embodiment, the underlying layer 122 is present everywhere below a bottom surface of the sacrificial gate layer 120. Hence, the underlying layer 122 may be the etch stop layer in both the active region (where it covers the fins 112) and in the isolation region (where it covers the STI layer 114). In some embodiments, after completing the recess etch, the exposed upper portion of the silicon fins 112 may be covered by a thin silicon dioxide layer formed by thermal oxidation process. With the thermally grown silicon dioxide covering the silicon fins 112 in the active region, and with the STI layer 114, comprising silicon oxide, in the isolation region, the deposition step forming the underlying layer 122 becomes optional. In such embodiments, the sacrificial gate layer 120, comprising silicon, may be deposited without first depositing a layer, such as the underlying layer 122, to separate the silicon fins 112 from the silicon sacrificial gate layer 120. The etch stop layer in the active region may be the thermally grown silicon dioxide layer, and the etch stop layer in the isolation region may be the STI layer 114.

The topmost layer in FIG. 1 is a patterned masking layer 130 for the gate etch process used to etch openings in the sacrificial gate layer 120 to form a pattern of lines that defines L_{g}. In FIG. 1, the patterned masking layer 130 is a hard mask layer comprising silicon oxide, patterned using, for example, an extreme ultraviolet (EUV) lithography process. Openings 132 in the patterned masking layer 130 expose a surface of the sacrificial gate layer 120. The portion of the patterned masking layer 130 seen in FIG. 1 is designed to etch two lines in the active region and one line in the isolation region. A thickness of the patterned masking layer 130 may be from about 20 nm to about 100 nm. In various embodiments, the patterned masking layer 130 may comprise silicon oxide, silicon nitride, silicon oxynitride, or a combination thereof.

The embodiments in this disclosure are aRIE processes that follow a conventional two-step approach for etching a pattern of lines in a silicon-based semiconductor layer. In the two-step etch process, a first plasma etch process (commonly referred to as main etch) is performed to etch a pattern of lines, and a second plasma etch process (commonly referred to as overetch) may be performed in situ to etch the pattern of lines formed by the main etch further to completion. Typically, the main etch process removes a majority of the material that needs to be removed from the layer to be etched using a first plasma and the overetch process is performed using a second plasma, different from the first plasma to remove material from a lower portion of the lines to provide a vertical sidewall all the way to the base of the lines.

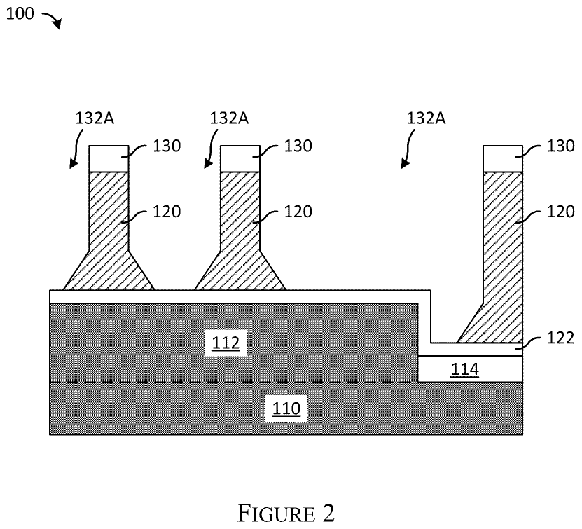

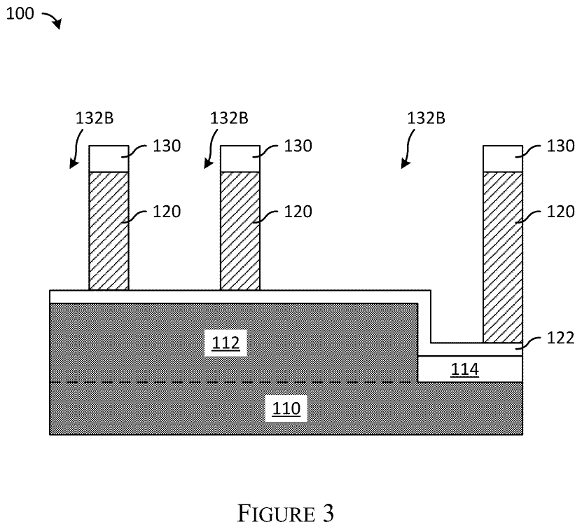

FIG. 2 illustrates a cross-sectional view of the substrate 100 at end of the main etch, and FIG. 3 illustrates the cross-sectional view after the overetch step is complete. Both the main etch and the overetch processes in the embodiments in this disclosure are aRIE processes.

An aRIE process is an ion-assisted chemical process, where energetic ions from a plasma are directed toward the substrate to sputter substrate material by breaking chemical bonds in a surface region to enhance chemical reactions with etchants from the plasma arriving at the surface. In some embodiments, a chlorine based etch chemistry may be used to etch silicon based semiconductor layers. In some other embodiments, other halogen based (e.g., bromine, fluorine, and iodine based) etch chemistries may be used. The etch process derives its anisotropy from a directionality of the ion flux. The chemical reactions not only produce volatile byproducts that are removed but also produce solid byproducts that may deposit on an exposed surface forming a passivating layer that blocks the etchants.

Performing the main etch process that results in the structure illustrated in FIG. 2 comprises generating the first plasma in a plasma processing chamber, where the substrate 100 is positioned on a substrate holder with the patterned masking layer 130 facing the plasma processing chamber for direct plasma processing. The plasma processing chamber is a vacuum chamber, where a gas discharge plasma may be generated using electromagnetic (EM) power to ionize a gas flowing over a substrate to be processed. A controlled flow of a discharge gas flowing through the plasma processing chamber may be maintained by a gas flow system. The gas supplied by the gas flow system to the plasma processing chamber may be a gaseous mixture comprising process gases, carrier gases, and additive gases. The gaseous mixture may be introduced into the plasma processing chamber through a gas inlet and ionized using EM power while flowing over the substrate 100 at controlled flow rates.

In the example embodiment, the gas flow during the main etch step includes a flow of molecular chlorine (Cl₂) at a flow rate of about 10 sccm to about 1000 sccm as the process gas and a flow of argon at a flow rate of about 10 sccm to about 1000 sccm as the carrier gas. In various embodiments, the process gas comprises a chemical etchant, for example, molecular chlorine (Cl₂), hydrogen chloride (HCl), and HBr, CF₄, C₂F₆, C₄F₈, HI, etc, and the carrier gas comprises an inert gas, for example, nitrogen, helium, neon, argon, krypton, and xenon. In various embodiments, a flow rate of the process gas may be from about 10 sccm to about 1000 sccm and a flow rate of the carrier gas may be from about 10 sccm to about 1000 sccm.

A gas outlet coupled to a vacuum pump of the gas flow system may remove gas from inside the plasma processing chamber and maintain a controlled low pressure. In the example embodiment, the gas pressure may be from about 5 mTorr to about 0.1 Torr, and from about 1 mTorr to about 1 Torr in various embodiments. The temperature of the substrate 100 may be controlled to be from about −70°C. to about 120°C. The gas pumped out through the gas outlet may include volatile byproducts produced in the plasma processing chamber during processing.

The EM power may be provided from multiple EM power sources coupled to several electrodes or antennas of the plasma processing chamber. The example embodiment may use a configuration known as an inductively coupled plasma (ICP) mode, but in some other embodiments, the plasma processing chamber may have a frequency resonance plasma (FREP) or a capacitively coupled plasma (CCP) configuration. In some embodiments, the first plasma may be generated using, for example, radio frequency (RF) source power of about 0.05 kW to about 2 kW at a frequency of about 10 MHz to about 2 GHz. In addition, a bias signal may be applied to enhance the directionality of the ion flux toward the substrate 100. The plasma comprises positively charged ions and negatively charged electrons to produce a charge neutral bulk plasma surrounded by a positively charged space charge region along the periphery, known as a plasma sheath. The plasma sheath results from balancing a flux of light and mobile electrons with a flux of the more massive and sluggish ions. Hence, the charge distribution in the plasma sheath adjacent to the substrate 100 sets up an electric field that accelerates ions from the bulk plasma toward the surface. The bias signal increases this electric field to accelerate ions to very high energies. In some embodiments, the bias signal may be an RF signal or a pulsed DC signal having bias power of about 0.05 kW to about 2 kW at a frequency of about 0.1 MHz to about 10 MHz.

During the main etch, a portion of the sacrificial gate layer 120 is removed by exposing the substrate 100 having the structure illustrated in FIG. 1 to the first plasma. As seen in FIG. 1, etchants from the plasma may interact with the exposed silicon surface the sacrificial gate layer 120 through the openings 132 in the patterned masking layer 130. As illustrated in FIG. 2, the first plasma has etched a pattern of lines in the sacrificial gate layer 120. By removing material using the patterned masking layer 130 as the etch mask, the main etch has extended the openings 132 in the patterned masking layer 130 deeper to form a pattern of openings 132A in FIG. 2. At the beginning of the main etch process, an upper portion of the sacrificial gate layer 120 is etched vertically, but as the etching progresses deeper, the lines start to flare and, at the end of the main etch, a lower portion of each of the lines has a foot along its base. It is also noted that a thickness of the hard mask material of the patterned masking layer 130 is reduced. The hard mask loss is mostly due to high energy ions sputtering some silicon oxide off the patterned masking layer 130.

Generally, the main etch has a relatively fast etch rate for high throughput and is optimized for control of CD and etch profile of an upper portion of the features to be etched in the silicon-based semiconductor layer. An upper portion of the openings 132A starts to form during an initial stage of the main etch when material starts being removed from the sacrificial gate layer 120. At this stage an aspect ratio of each of the openings 132A is small, hence even ions in the ion flux having relatively large angles with the vertical direction strike the bottom of the opening 132A without colliding with a sidewall of the opening 132A. Thus, the bottom of the opening 132A gets etched efficiently and, with the help of passivating material depositing on the exposed sidewall, the etch front progresses vertically to form the upper portion of the opening 132A with the vertical sidewall, as illustrated in FIG. 2.

As the main etch progresses, the aspect ratio of the opening 132A increases. The higher aspect ratio makes it more difficult for ions to reach the bottom of the opening 132A, especially around the edges. Although the bias signal (mentioned above) enhances the directionality of the ion flux incident on the substrate 100, there is a distribution of ions described by an ion angle distribution (IAD) and an ion energy distribution (IED). Ions in the IAD that have trajectories along larger angles from the vertical suffer worse shadowing effects. The shadowing reduces the etch rate at the bottom in a region close to the edges of the bottom surface. Non-vertical trajectories also lead to more collisions of ions with the sidewall as the opening 132A deepens. The collisions with the sidewall randomizes the directions of ion velocities. The loss of directionality broadens the IAD, that is, more of the ions move along off-vertical trajectories. This escalates the ion shadowing, which hinders vertical etching. Typically, collisions with the sidewall are inelastic collisions; the loss of ion energy slows down the etch rate near the edges in the lower portion of the opening 132A.

Having acquired kinetic energy from the vertical electric field in the plasma sheath, the high energy ions in the IED have a high vertical component of velocity, resulting in near vertical trajectories. As the aspect ratio increases toward the lower portion of the opening 132A, a smaller fraction of the ions (only those at the higher energy end of the IED) reach the bottom surface of the opening 132A without colliding with the sidewall. As mentioned above, the bias signal enhances the directionality of the ion flux by increasing the accelerating field. While this is advantageous for vertical etching, there is a tradeoff with etch selectivity. Increasing ion energy increases the hard mask loss by sputtering more material off the patterned masking layer 130. The lower energy ions in the IED are usually distributed more isotropically in the IAD. Having lower velocity, the low energy ion in the IED spends a longer time in transit in the openings 132A, which increases a chance of being scattered by colliding with another particle, for example, a neutral particle from the plasma diffusing down the opening 132A. Collisions with neutrals randomizes ion motion, resulting in more isotropic etching.

As explained above, the aspect ratio dependence of the main etch may cause the etch rate in the openings 132A to drop faster near the edges relative to the center as the etch progresses deeper to a lower portion of the openings 132A. Thus, the sidewall profile of the openings 132A in FIG. 2 shows significant footing at the end of the etch process. In some embodiments, such as the example embodiment illustrated in FIG. 2, the main etch is terminated after exposing an underlying layer below the silicon-based semiconductor layer such as the silicon oxide underlying layer 122 below the silicon sacrificial gate layer 120. In such embodiments, the main etch may be a timed etch process or be terminated using an endpoint signal.

After completing the main etch process (i.e., the first plasma etch process) using the first plasma, the second plasma etch process (referred to here as the overetch process) may be performed in situ to remove the foot in the lines etched in the silicon-based semiconductor layer by the main etch, for example, the foot in the pattern of lines in the sacrificial gate layer 120, as seen in FIG. 2. The overetch process vertically etches the foot and extends the openings to their final depth to complete the two-step etch process for etching a pattern of lines in the silicon-based semiconductor layer. The cross-sectional view of the substrate 100 at end of the overetch step (illustrated in FIG. 3) shows that the overetch process has vertically etched the pattern of lines in the sacrificial gate layer 120 and extended the openings 132A to form openings 132B without creating a notch or a re-entrant edge.

As mentioned above, the overetch process is another aRIE process. Performing the overetch process comprises generating the second plasma (different from the first plasma) from a gaseous mixture comprising a carrier gas, a first gas comprising an etchant, and a second gas comprising chemical agents for scavenging the etchant and for depositing a passivating layer over surfaces to be protected from being etched by the etchant. The chemical action of the chemical agents are described in further detail below.

In the example embodiment, the carrier gas in the gas flow during the overetch step may be argon having a flow rate of about 10 sccm to about 1000 sccm. The first gas used for the example embodiment may be molecular chlorine (Cl₂) at a flow rate of about 10 sccm to about 1000 sccm and the second gas may be silane (SiH₄) at a flow rate of about 10 sccm to about 1000 sccm. In various embodiments, the carrier gas comprises an inert gas, for example, nitrogen, helium, neon, argon, krypton, and xenon at a flow rate of about 10 sccm to about 1000 sccm.

As mentioned above, silicon-based semiconductor layers may be etched using chlorine chemistry. In various embodiments, the first gas may be molecular chlorine (Cl₂), hydrogen chloride (HCl), or a combination of thereof. In some embodiments, the first gas may be having the same chemical composition as the process gas used for the main etch process.

The second gas (the gas containing chemical agents for scavenging the etchant and for depositing a passivating layer) comprises a compound of hydrogen with Si, Br, I, P, or S. Atomic chlorine is scavenged by reacting with a hydrogen atom of the second gas. Specifically, the reaction progresses along a reaction coordinate from the transition state to an energetically favored state comprising volatile HCl and a deposition precursor. The deposition precursor may participate in further chemical reactions that result in deposition of a protective layer comprising a protective material on various surfaces exposed to the second plasma. In the example embodiment, where the second gas is SiH₄, the scavenging reaction produces the deposition precursor SiH₃ and the protective material is Si, SiH, SiH₂, and SiH₃ which may be subsequently further modified by the plasma environment.

In some embodiments, the second gas comprises HBr, HI, PH₃, or H₂S. In these embodiments, the deposition precursors comprise Br, I, PH₂, and HS, respectively, and the protective materials comprise Br₂, I₂, P, PH, PH₂, and HS, respectively, which may be subsequently further modified by the plasma environment. In some embodiments, the second gas is a silicon-containing gas. In some embodiments, the silicon-containing second gas has a composition of SiHₙX₄₋ₙ (n=4, 3, 2, 1), or Si₂HₙX₆₋ₙ (n=6, 5, 4, 3, 2, 1), or a combination thereof, where X is a halogen. In these embodiments, the deposition precursor and the protective material are silicon-containing materials, e.g. SiHₘXₙ, where (m+n)<4. In some other embodiments, the silicon containing second gas has a composition of SiHₙX₄₋ₙ (n=3, 2, 1, 0), or a combination thereof, where X is an alkane group. Examples of alkane group include CH₃, C₂H₅, n-C₃H₈, and i-C₃H₈. In these embodiments, the deposition precursor and the protective material are silicon and carbon-containing materials, e.g. SiHₘXₙ, where (m+n)<4.

In various embodiments, the flow rate of the first gas may be from about 10 sccm to about 1000 sccm, and the flow rate of the second gas may be from about 10 sccm to about 1000 sccm.

In the example embodiment, the gas pressure may be from about 5 mTorr to about 0.1 Torr, and from about 1 mTorr to about 1 Torr in various embodiments. The temperature of the substrate 100 may be controlled at a temperature of about −70°C to about 120°C.

In some embodiments, the second plasma may be generated using, for example, radio frequency (RF) source power of about 0.05 kW to about 2 kW at a frequency of about 10 MHz to about 2 GHz. In addition, a bias signal may be applied to enhance the directionality of the ion flux toward the substrate 100. In some embodiments, the bias signal may be an RF signal or a pulsed DC signal having bias power of about 0.05 kW to about 2 kW at a frequency of about 0.1 MHz to about 10 MHz.

The overetch process is optimized for controlling the CD and etch profile near the base of the lines etched in the sacrificial gate layer 120. The etch rate for the overetch process may be lower than that for the main etch process to achieve better control of the amount of material removed and the final depth of the openings. Vertical etching of the foot along the base of the lines etched in the sacrificial gate layer 120 may be aided by scavenging neutral chlorine atoms present in the lower portion of the openings 132A. As explained above, hydrogen atoms provided by the second gas reacts with chlorine atoms to produce volatile HCl, thus scavenging neutral atomic chlorine. Scavenging the neutral atomic chlorine increases a ratio of ions to neutral species. Generally, a higher ion to neutral ratio produces a more vertical profile with less taper. As explained above, the footing is mainly due to worse ion shadowing in the lower portion of the openings 132A. Thus, having a sufficiently high supply of ions relative to neutrals by scavenging neutral chlorine atoms helps the second plasma to remove the foot from the lower portion of the openings 132A to form the openings 132B in FIG. 3. As illustrated in FIG. 3, sidewalls of the openings 132B are vertical; they have no foot, notch or re-entrant edge.

Deposition of the protective material helps improve etch selectivity. In the example embodiment, the sidewall surface exposed in the openings 132B by the overetch process may be protected from being laterally etched by depositing a protective layer over the sidewall using the deposition precursor produced by the scavenging reaction, as described above. Depositing the protective layer over the patterned masking layer 130 reduces hard mask loss during etching. Likewise, deposition of protective material over exposed portions of the underlying layer 122 prevents etching through the underlying layer 122 and exposing the silicon fin 112 to etchants. Note that the protective layer comprising the protective material is not shown in FIG. 3. The protective material, being exposed to the second plasma, is also being sputter etched during the overetch process. Furthermore, it may get removed by a subsequent surface clean process step.

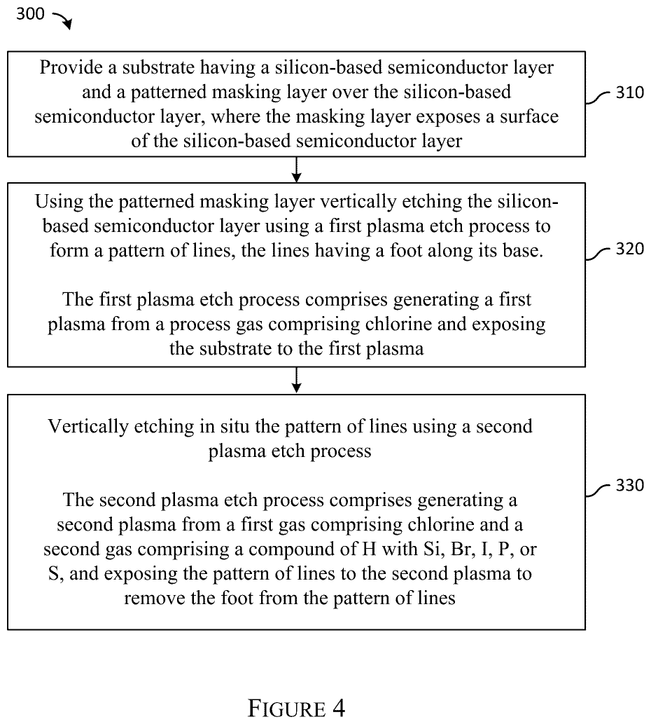

FIG. 4 illustrates a flow chart of the method 300 for plasma etching vertical features in a silicon-based semiconductor layer of a substrate. The method 300 has been described in detail above with reference to FIGS. 1-3 and is summarized in the flow chart in FIG. 4.

Box 310 of the flowchart in FIG. 4 indicates that a substrate having a silicon-based semiconductor layer and a patterned masking layer disposed over the silicon-based semiconductor layer is provided. The patterned masking layer exposes a surface of the silicon-based semiconductor layer.

In box 320 of the flow chart of the method 300, a first plasma etch process is performed that vertically etches the silicon-based semiconductor layer using patterned masking layer to form a pattern of lines. One or more lines of the pattern of lines have a foot along its base. The first plasma etch process comprises generating a first plasma from a process gas comprising chlorine, and exposing the substrate to the first plasma.

As indicated in box 330 of the flow chart of the method 300, a second plasma etch process is performed in situ. The second plasma etch process vertically etches the pattern of lines. In the second plasma etch process, a second plasma is generated from a first gas comprising chlorine and a second gas comprising a compound of hydrogen with Si, Br, I, P, or S. The pattern of lines is exposed to the second plasma to remove the foot from each line of the pattern of lines.

Example embodiments of the invention are described below. Other embodiments can also be understood from the entirety of the specification as well as the claims filed herein.

Example 1. A method for plasma etching in a plasma processing chamber, where the method includes providing a substrate having a silicon-based semiconductor layer disposed over an etch stop layer and a patterned masking layer disposed over the silicon-based semiconductor layer, the patterned masking layer exposing a surface of the silicon-based semiconductor layer; using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process including generating a first plasma; and vertically etching in situ the pattern of lines using a second plasma etch process, the second plasma etch process including generating a second plasma from a first gas including chlorine and a second gas including a compound of hydrogen with Si, Br, I, P, or S, the second plasma being different from the first plasma, and exposing the pattern of lines to the second plasma to remove the foot from the pattern of lines.

Example 2. The method of example 1, where the first gas includes molecular chlorine.

Example 3. The method of one of examples 1 or 2, where the second gas includes HBr, HI, PH₃, or H₂S.

Example 4. The method of one of examples 1 to 3, where the second gas includes a Si-containing gas.

Example 5. The method of one of examples 1 to 4, where the Si-containing gas has a composition of SiHₙX₄₋ₙ (n=4, 3, 2, 1) or Si₂HₙX₆₋ₙ (n=6, 5, 4, 3, 2, 1), where X is a halogen.

Example 6. The method of one of examples 1 to 5, where the Si-containing gas has a composition of Si-containing gas is SiHₙX₄₋ₙ (n=3, 2, 1, 0), where X includes an alkane group.

Example 7. The method of one of examples 1 to 6, where the Si-containing gas has a composition of SiH₄ or SiH₂Cl₂.

Example 8. A method for plasma etching, where the method includes flowing a gas over a substrate in a plasma processing chamber, the substrate including: an etch stop layer; a patterned silicon-based semiconductor layer disposed over the etch stop layer, the pattern including lines and openings between the lines, each of the lines having a foot along its base and each of the openings exposing a surface of an etch stop layer, and a patterned masking layer disposed over the patterned silicon-based semiconductor layer, the patterned masking layer being a topmost layer of the substrate; generating a plasma by ionizing the gas in the plasma processing chamber, the gas including: a first gas including an etchant; and a second gas including a scavenging and deposition agent; and exposing the substrate to the plasma to remove the foot, the exposing including scavenging the etchant while depositing a protective layer over the patterned masking layer.

Example 9. The method of example 8, further including depositing the protective layer over exposed sidewalls of openings between lines.

Example 10. The method of one of examples 8 or 9, further including depositing the protective layer over the etch stop layer.

Example 11. The method of one of examples 8 to 10, where the first gas includes molecular chlorine.

Example 12. The method of one of examples 8 to 11, where the second gas includes HBr, HI, PH₃, or H₂S.

Example 13. The method of one of examples 8 to 12, where the second gas includes a Si-containing gas.

Example 14. The method of one of examples 8 to 13, where the Si-containing gas has a composition of SiHₙX₄₋ₙ (n=3, 2, 1, 0) or Si₂HₙX₆₋ₙ (n=6, 5, 4, 3, 2, 1), where X is a halogen.

Example 15. The method of one of examples 8 to 14, where the Si-containing gas has a composition of Si-containing gas is SiHₙX₄₋ₙ (n=3, 2, 1, 0), where X includes an alkane group.

Example 16. The method of one of examples 8 to 15, where the Si-containing gas has a composition of SiH₄ or SiH₂Cl₂.

Example 17. A method for plasma etching in a plasma processing chamber, where the method includes providing a substrate having a silicon-based semiconductor layer disposed over an etch stop layer and a patterned masking layer disposed over the silicon-based semiconductor layer, the patterned masking layer exposing a surface of the silicon-based semiconductor layer; using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process including generating a first plasma from a first gas including chlorine, and exposing the substrate to the first plasma; and vertically etching in situ the pattern of lines using a second plasma etch process, the second plasma etch process including generating a second plasma from the first gas and a second gas including a compound of hydrogen with Si, Br, I, P, or S, and exposing the pattern of lines to the second plasma to remove the foot from the pattern of lines.

Example 18. The method of example 17, where the second gas includes HBr, HI, PH₃, or H₂S.

Example 19. The method of one of examples 17 or 18, where the second gas includes a Si-containing gas.

Example 20. The method of one of examples 17 to 19, where the Si-containing gas has a composition of SiHₙX₄₋ₙ (n=3, 2, 1, 0) or Si₂HₙX₆₋ₙ (n=6, 5, 4, 3, 2, 1), where X is a halogen.

Example 21. The method of one of examples 17 to 20, where the Si-containing gas has a composition of Si-containing gas is SiHₙX₄₋ₙ (n=3, 2, 1, 0), where X includes an alkane group.

Example 22. The method of one of examples 17 to 21, where the Si-containing gas has a composition of SiH₄ or SiH₂Cl₂.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for plasma etching in a plasma processing chamber, the method comprising:
providing a substrate having a silicon-based semiconductor layer disposed over an etch stop layer and a patterned masking layer disposed over the silicon-based semiconductor layer, the patterned masking layer exposing a surface of the silicon-based semiconductor layer;
using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process comprising generating a first plasma; and
vertically etching in situ the pattern of lines using a second plasma etch process, the second plasma etch process comprising:
generating a second plasma from a first gas comprising chlorine and a second gas comprising a compound of hydrogen with Si, Br, I, P, or S, the second plasma being different from the first plasma, and
exposing the pattern of lines to the second plasma to remove the foot from the pattern of lines.

2. The method of claim 1, wherein the first gas comprises molecular chlorine.

3. The method of claim 1, wherein the second gas comprises HBr, HI, PH₃, or H₂S.

4. The method of claim 1, wherein the second gas comprises a Si-containing gas.

5. The method of claim 4, wherein the Si-containing gas has a composition of SiHₙX₄₋ₙ (n=4, 3, 2, 1) or Si₂HₙX₆₋ₙ (n=6, 5, 4, 3, 2, 1), where X is a halogen.

6. The method of claim 4, wherein the Si-containing gas has a composition of Si-containing gas is SiHₙX₄₋ₙ (n=3, 2, 1, 0)_{,} where X comprises an alkane group.

7. The method of claim 4, wherein the Si-containing gas has a composition of SiH₄ or SiH₂Cl₂.

8. A method for plasma etching, the method comprising:
flowing a gas over a substrate in a plasma processing chamber, the substrate comprising:
an etch stop layer;
a patterned silicon-based semiconductor layer disposed over the etch stop layer, the pattern comprising lines and openings between the lines, each of the lines having a foot along its base and each of the openings exposing a surface of an etch stop layer, and
a patterned masking layer disposed over the patterned silicon-based semiconductor layer, the patterned masking layer being a topmost layer of the substrate;
generating a plasma by ionizing the gas in the plasma processing chamber, the gas comprising:
a first gas comprising an etchant; and
a second gas comprising a scavenging and deposition agent; and
exposing the substrate to the plasma to remove the foot, the exposing comprising scavenging the etchant while depositing a protective layer over the patterned masking layer.

9. The method of claim 8, further comprising depositing the protective layer over exposed sidewalls of openings between lines.

10. The method of claim 8, further comprising depositing the protective layer over the etch stop layer.

11. The method of claim 8, wherein the first gas comprises molecular chlorine.

12. The method of claim 8, wherein the second gas comprises HBr, HI, PH₃, or H₂S.

13. The method of claim 8, wherein the second gas comprises a Si-containing gas.

14. The method of claim 13, wherein the Si-containing gas has a composition of SiHₙX₄₋ₙ (n=4, 3, 2, 1) or Si₂HₙX₆₋ₙ (n=6, 5, 4, 3, 2, 1), where X is a halogen.

15. The method of claim 13, wherein the Si-containing gas has a composition of Si-containing gas is SiHₙX₄₋ₙ (n=3, 2, 1, 0)_{,} where X comprises an alkane group.

16. A method for plasma etching in a plasma processing chamber, the method comprising:
providing a substrate having a silicon-based semiconductor layer disposed over an etch stop layer and a patterned masking layer disposed over the silicon-based semiconductor layer, the patterned masking layer exposing a surface of the silicon-based semiconductor layer;
using the patterned masking layer as an etch mask, vertically etching the silicon-based semiconductor layer using a first plasma etch process to form a pattern of lines and expose portions of the underlying etch stop layer, one or more lines of the pattern of lines having a foot along its base, the first plasma etch process comprising:
generating a first plasma from a first gas comprising chlorine, and
exposing the substrate to the first plasma; and
vertically etching in situ the pattern of lines using a second plasma etch process, the second plasma etch process comprising:
generating a second plasma from the first gas and a second gas comprising a compound of hydrogen with Si, Br, I, P, or S, and
exposing the pattern of lines to the second plasma to remove the foot from the pattern of lines.

17. The method of claim 16, wherein the second gas comprises HBr, HI, PH₃, or H₂S.

18. The method of claim 16, wherein the second gas comprises a Si-containing gas.

19. The method of claim 18, wherein the Si-containing gas has a composition of SiHₙX₄₋ₙ (n=4, 3, 2, 1) or Si₂HₙX₆₋ₙ (n=6, 5, 4, 3, 2, 1), where X is a halogen.

20. The method of claim 18, wherein the Si-containing gas has a composition of Si-containing gas is SiHₙX₄₋ₙ (n=3, 2, 1, 0)_{,} where X comprises an alkane group.
